(19) United States
(12) Patent Application Publication
(10) Pub. No.: US 2015/0125622 A1
(43) Pub. Date: May 7, 2015

(54) SYSTEMS AND METHODS FOR HIGH AND ULTRA-HIGH VACUUM PHYSICAL VAPOR DEPOSITION WITH IN-SITU MAGNETIC FIELD

(71) Applicant: The Trustees of Columbia University in the City of, New York, NY (US)

(72) Inventors: KENNETH L. SHEPARD, Ossining, NY (US); William E. Bailey, New York, NY (US); Noah Andrew Sturcken, New York, NY (US); Cheng Cheng, New York, NY (US); Sioan Zohar, Lemont, IL (US)

(73) Assignee: The Trustees of Columbia University in HIe City of, New York, NY (US)

(21) Appl. No.: 14/504,083

(22) Filed: Oct. 1, 2014

Related U.S. Application Data
(63) Continuation of application No. PCT/US2013/032359, filed on Mar. 15, 2013.
(60) Provisional application No. 61/320,095, filed on Apr. 1, 2010.

(51) Int. Cl. C23C 14/50; C23C 14/35; C23C 14/46; C23C 14/30

(52) U.S. Cl. CPC C23C 14/505; C23C 14/30; C23C 14/35; C23C 14/46
USPC 427/547; 118/723 EB; 118/723 CB; 118/722; 204/192.12; 204/192.11

(57) ABSTRACT

Systems and methods for high and ultra-high vacuum physical vapor deposition with in-situ magnetic field are disclosed herein. An exemplary method for depositing a film in an evacuated vacuum chamber can include introducing a sample into the vacuum chamber. The sample can be rotated. A magnetic field can be applied that rotates synchronously with the rotating sample. Atoms can be deposited onto the sample while the sample is rotating with the magnetic field to deposit a film while the magnetic field induces magnetic anisotropy in the film.

### CROSS REFERENCE TO RELATED APPLICATION

This application is a continuation of PCT/US2013/032359, filed Mar. 15, 2013, which claims priority from U.S. Provisional Application No. 61/620,095, filed Apr. 4, 2012, which is incorporated by reference herein.

### STATEMENT REGARDING FEDERALLY SPONSORED RESEARCH

This invention is made with government support from the U.S. Department of Energy under Grant No. DE-EE0002892 and the National Science Foundation under Grant No. ECCS0925829. The Government has certain rights in the invention.

### BACKGROUND

The disclosed subject matter relates to techniques for high and ultra-high vacuum physical vapor deposition with in-situ magnetic field. Well-defined magnetic anisotropy can be used for soft magnetic materials used in a wide range of applications, for example thin-film magnetic recording heads, magnetic random access memory, on-chip magnetic field sensors, and power management devices. In order to achieve in such devices higher sensitivity, smaller device sizes, and lower power dissipation, among other things, it can be useful for magnetic thin films to have enhanced soft magnetic properties. Reduced coercive field (H_{C}) and enhanced magnetic permeability (χₘ) along particular axes of the devices can be desirable.

Techniques for inducing uniaxial or unidirectional anisotropy in an alloy thin film, either amorphous or polycrystalline, can include deposition or postannealing in the presence of a magnetic field. Deposition in the presence of a magnetic field can save a processing procedure and can be useful for multilayer devices or device structures that are temperature-sensitive. The magnetic field applied during deposition can be applied by a permanent magnet fixed to a sample holder, and the entire sample holder-magnet assembly can rotate during deposition, which can be by sputtering, evaporative deposition, or other physical vapor deposition process. It can be difficult to change the direction of anisotropy in different layers of a multilayer device.

There exists a need for an improved technique for physical vapor deposition with in-situ magnetic field.

### SUMMARY

Systems and methods for high and ultra-high vacuum physical vapor deposition with in-situ magnetic field are disclosed herein.

In one aspect of the disclosed subject matter, methods for depositing a film in an evacuated vacuum chamber are disclosed. An exemplary method can include introducing a sample into the vacuum chamber. The sample can be rotated, and a magnetic field can be applied that rotates synchronously with the rotating sample. Atoms can be deposited onto the sample while the sample is rotating with the magnetic field. Thus, a portion of the atoms can be deposited on the sample as the film while the magnetic field induces magnetic anisotropy in the film.

In some embodiments, the magnetic field can rotate synchronously with the sample at a first phase difference. The magnetic field can be generated by applying sinusoidal currents through first and second pairs of coils wrapped around a quadrupole electromagnet core, where the sinusoidal current in the first pair of coils is π/4 out of phase from the sinusoidal current in the second pair of coils. In some embodiments, a second magnetic field can be applied that rotates synchronously with the sample at a second phase difference that is different than the first phase difference. Atoms can be deposited onto the sample while the sample is rotating with the second magnetic field to cause a portion of the atoms to be deposited on the sample as a second layer of film while the second magnetic field induces magnetic anisotropy in the second film.

In some embodiments, the applied magnetic field that rotates synchronously with the sample at a first phase difference can be adjusted in-situ to have a second phase difference. Thus a second magnetic field that rotates synchronously with the sample at a second phase difference can be applied after applying the first magnetic field. In some such embodiments, the first phase difference and the second phase difference can be π/2 out of phase. The film layers deposited in the magnetic fields with the first and second phase differences can thus have orthogonal anisotropy. The application of a magnetic field and atom depositing procedure can be repeated in order to deposit successive layers of film.

In some embodiments, the system can use one of direct current (DC) magnetron sputtering, radio frequency (RF) sputtering, or ion beam sputtering (IBS), ion beam deposition (IBD), or electron beam evaporation. In some embodiments, the frequency of the rotation can be 1 revolution per second or less.

In some embodiments, the sample can be centered in the vacuum chamber. The atoms can be sputtered from at least one target disposed in the vacuum chamber. The targets can be symmetrically arranged. The targets can also be inclined towards the sample.

In another aspect of the disclosed subject matter, systems for vacuum film deposition are disclosed. An exemplary system can include a vacuum chamber. A physical vapor deposition device can be disposed in the vacuum chamber. A sample holder can be disposed in the vacuum chamber. A motor can be configured to rotate the sample holder. A magnetic field source can be adapted to rotate a magnetic field synchronously with the sample holder.

In some embodiments, the magnetic field source can be a quadrupole electromagnet. The quadrupole electromagnet can include a metallic core, a first pair of coils, and a second pair of coils. The metallic core can include a circular core ring and first, second, third, and fourth poles equidistantly spaced around the interior of the circular core ring. Each of the poles can protrude towards the center of the circular core ring. The first pair of coils can include a first coil wrapped around the metallic core between the first and fourth poles and a second coil wrapped around the metallic core between the second and third poles. The second pair of coils can include a third coil wrapped around the metallic core between the first and second poles and a fourth coil wrapped around the metallic core between the third and fourth poles.

A motor controller can be configured to control the motor. At least one power supply can be configured to generate alternating current (AC) currents through the first and second pairs of coils. A data acquisition device can be connected to the motor controller and the at least one power supply to synchronize the rotating of the magnetic field and the rotating of the sample holder.

In some embodiments, the quadrupole electromagnet can be positioned to be centered with the sample holder. Thus a uniform in-plane magnetic field can exist across the sample holder. The sample holder can be configured such that a sample placed thereon will face the bottom of the vacuum chamber.

In some embodiments, the quadrupole electromagnet can be configured to generate a magnetic field that rotates synchronously with the sample holder at a phase difference. In some embodiments, the physical vapor deposition device can be one of a DC magnetron sputtering system, a RF sputtering system, an IBS system, and IBD system, or an electron beam evaporation system. In some embodiments, the physical vapor deposition device can be a sputtering device adapted to sputter atoms from at least one sputter target disposed in the vacuum chamber.

The accompanying drawings, which are incorporated and constitute part of this disclosure, illustrate embodiments of the disclosed subject matter and serve to explain the principles of the disclosed subject matter.

### BRIEF DESCRIPTION OF THE DRAWINGS

FIG. 1 shows an exemplary system for vacuum film depositing in accordance with some embodiments of the disclosed subject matter.

FIG. 2 shows an exemplary core of an electromagnet in accordance with some embodiments of the disclosed subject matter.

FIG. 3 shows an exemplary electromagnet in accordance with some embodiments of the disclosed subject matter.

FIG. 4 shows (a) an exemplary schematic of the vector sum of two orthogonal magnetic fluxes at the center point of an electromagnet and (b) an exemplary graph of the correspondence between the sputtering field and the applied AC currents in accordance with some embodiments of the disclosed subject matter.

FIG. 5 shows an exemplary graph of the linear relationship between the applied voltage control and measured magnitude of the rotating magnetic field in accordance with some embodiments of the disclosed subject matter.

FIG. 6 shows an exemplary alignment of a sample on a sample holder in accordance with some embodiments of the disclosed subject matter.

FIG. 7 shows (a) an exemplary BH loop of a first sample in a first set, (b) an exemplary BH loop of a second sample in a first set, (c) an exemplary BH loop of a first sample in a second set, and (d) an exemplary FMR Kittel relation of the first sample in the second set in accordance with some embodiments of the disclosed subject matter.

FIG. 8 shows an exemplary graph of the change of ferromagnetic resonance field H₀ at 4 GHz, as the angle α between the FMR bias field H_{B} and the sample reference axis R varies from 0° to 180° in accordance with some embodiments of the disclosed subject matter.

FIG. 9 shows an exemplary graph of the change of ferromagnetic resonance field H₀ at 4 GHz, as the initial phase of the rotating magnetic field φ varies from 0° to 180° in accordance with some embodiments of the disclosed subject matter.

FIG. 10 shows an exemplary method for depositing a film in an evacuated vacuum chamber in accordance with some embodiments of the disclosed subject matter.

Throughout the drawings, similar reference numerals and characters, unless otherwise stated, are used to denote like features, elements, components or portions of the illustrated embodiments. Moreover, while the disclosed subject matter will now be described in detail with reference to the FIGS., it is done so in connection with the illustrative embodiments.

### DETAILED DESCRIPTION

The disclosed subject matter provides techniques for high and ultra-high vacuum physical vapor deposition with in-situ magnetic field. A magnetic field can be applied across a rotating sample during physical vapor deposition in order to deposit a magnetically anisotropic film on the sample. The magnetic field can rotate synchronously with the rotating sample. There can be a phase difference between the rotating sample and the rotating magnetic field. The anisotropy of a layer of film can be adjusted by adjusting the phase difference. A rotating field can be generated by applying alternating current (AC) currents to the coils of an electromagnet without moving the electromagnet. The phase difference between the rotating magnetic field and the rotating sample can be adjusted by adjusting the AC currents in the coils without moving the electromagnet.

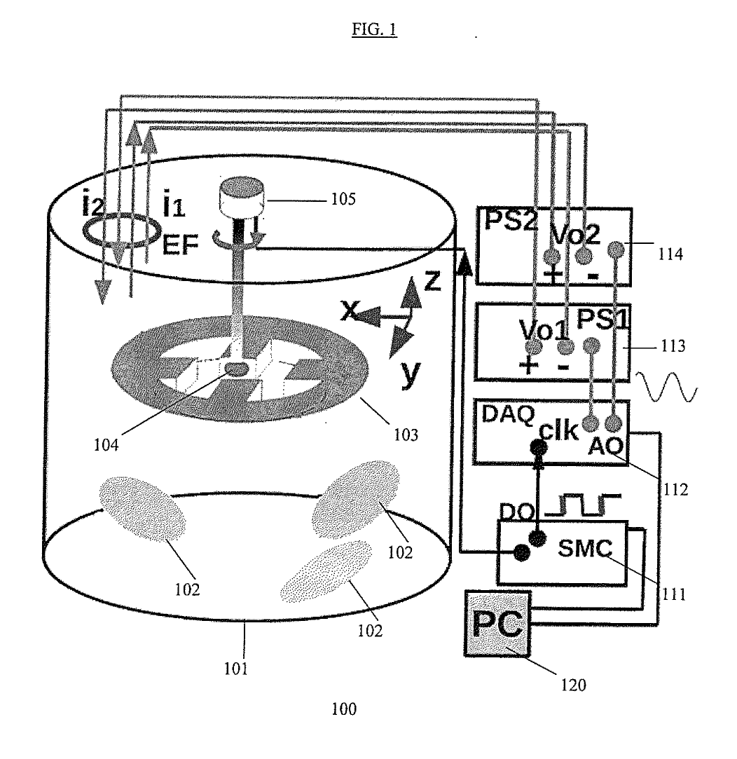

Referring to FIG. 1, an exemplary system 100 for vacuum film depositing is shown. The system 100 can include a vacuum chamber 101. For example, the vacuum chamber 101 can have a base pressure up to 10⁻⁶ torr, although higher and lower base pressures are contemplated within the scope of the disclosed subject matter depending on the particular application. A physical vapor deposition device (not pictured) can be adapted to deposit atoms onto the surface of a sample. For example, the physical vapor deposition device can be a sputtering device, an ion beam deposition system, an electron-beam evaporation system, or any other suitable physical vapor deposition system. For example, a sputtering device can include a direct current (DC) magnetron sputtering system, a radio frequency (RF) sputtering system, an ion beam sputtering (IBS) system, or any other suitable sputtering system. The following examples will be discussed primarily in the context of sputtering, but it will be apparent to those skilled in the art that the teachings herein can apply in the context of any form of physical vapor deposition. By way of example and not limitation, at least one sputter target 102 can be disposed in the vacuum chamber 101. A sputtering device (not pictured) can be adapted to sputter atoms from at least one sputter target 102. A sample holder 104 can be disposed in the vacuum chamber 101. A motor 105 can be configured to rotate the sample holder 104. A magnetic field source 103 can be adapted to rotate a magnetic field synchronously with the sample holder 104.

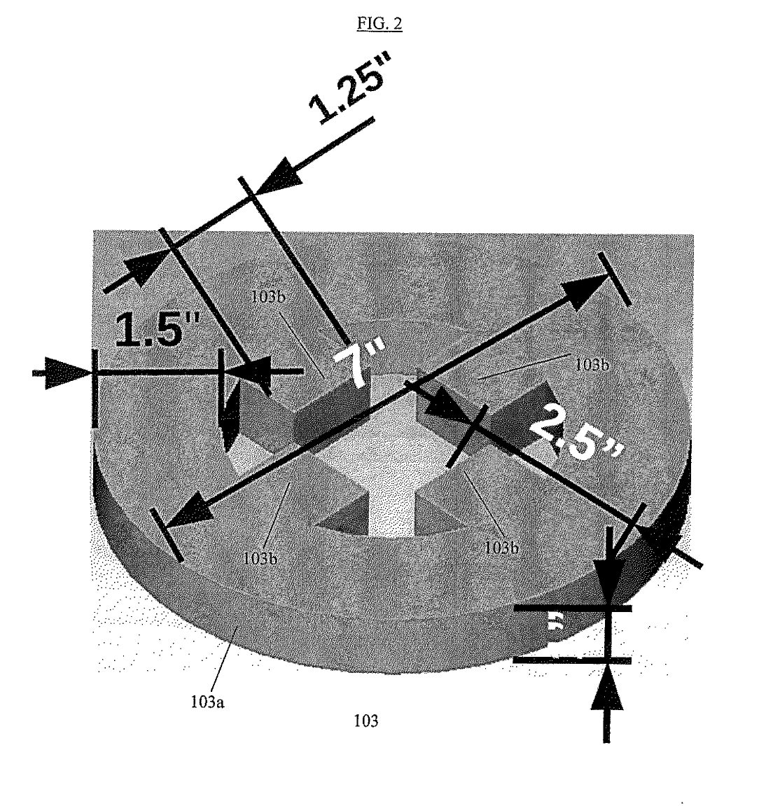

By way of example and not limitation, the magnetic field source 103 can be a quadrupole electromagnet. The quadrupole electromagnet can be custom designed to meet the specifications of the vacuum film depositing system 100. For example, referring to FIG. 2, the magnetic field source 103 can include a metallic core. The metallic core can include a circular core ring 103a and first, second, third, and fourth poles 103b. The quadrupole electromagnet can be well fitted in the vacuum chamber 101, leaving enough space at the interior of the metallic core ring 103a for accommodating the sample holder 104. The power of the electromagnet can be suited for the desired magnetic field strength, depending on the magnitude of the magnetic anisotropy desired in the film. The poles 103b can be equidistantly spaced around the interior of the circular core ring 103a. Each of the poles 103b can protrude towards the center of the circular core ring 103a.

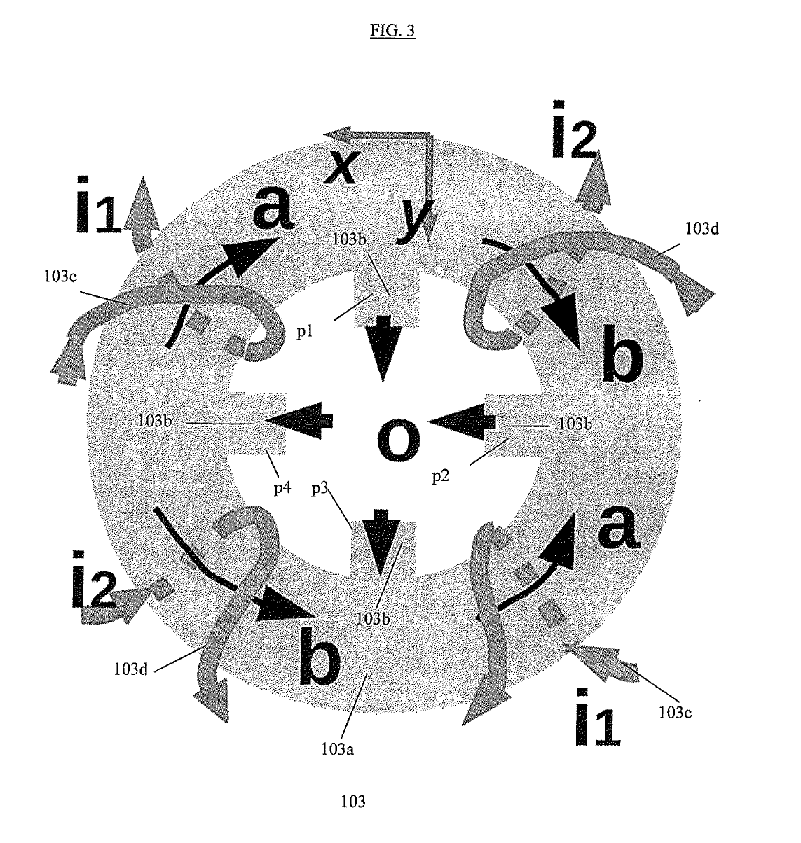

By way of example and not limitation, the magnetic field source 103 can include coils. For example, referring to FIG. 3, the magnetic field source 103 can include a first pair of coils 103c and a second pair of coils 103d. Referring to the first, second, third, and fourth poles 103b as p1, p2, p3, and p4, respectively, the first pair of coils 103c can include a first coil wrapped around the metallic core 103a between p4 and p1 and a second coil wrapped around the metallic core 103a between p2 and p3. The second pair of coils 103d can include a third coil wrapped around the metallic core 103a between p1 and p2 and a fourth coil wrapped around the metallic core 103a between p3 and p4.

Referring again to FIG. 1, by way of example and not limitation, the motor 105 can be controlled by a motor controller 111. At least one power supply can generate AC currents through the pairs of coils 103c and 103d. For example, a first power supply 113 and a second power supply 114 can generate AC currents through the first pair of coils 103c and the second pair of coils 103d, respectively. A data acquisition device 112 can be connected to the motor controller 111 and the power supplies 113 and 114 to synchronize the rotating of the magnetic field and the sample holder 104. In some embodiments, one or more of the motor controller 111, the data acquisition device 112, the first power supply 113, or the second power supply 114 can be connected to a personal computer 120.

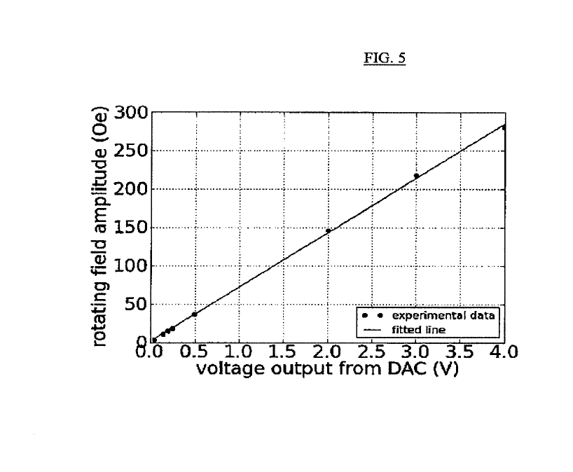

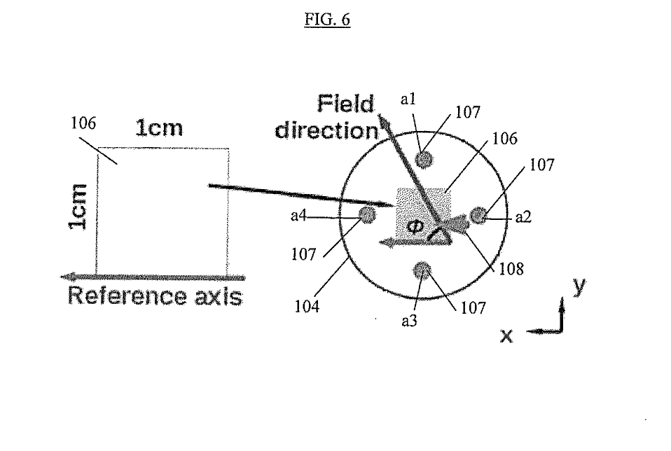

By way of example and not limitation, the magnetic field source 103 can be a quadrupole electromagnet, as described above, positioned to be centered with the sample holder 104. A substantially uniform magnetic field can thus be applied across the sample holder 104. The magnitude of the magnetic field can vary depending on the magnitude of the magnetic anisotropy desired in the film. By way of example and not limitation, the magnetic field can be in the range of 0-300 Oe, as illustrated in FIG. 5, discussed below. The sample holder 104 can be configured such that a sample placed thereon will be centered in the vacuum chamber. Atoms can be sputtered from targets 102 disposed at the bottom of the vacuum chamber 101. By way of example and not limitation, the sputtering device can be a DC magnetron sputtering system, a RF magnetron sputtering system, or an IBS system. For example, certain devices are necessary to cause the sputtering process. In an exemplary DC magnetron sputtering system, the targets 102 can be mounted on sputtering guns (not pictured) and at least one power supply (not pictured) can be attached to the sputtering guns. For example, an Advanced Energy MDX 500 Magnetron Drive can be used as the power supply and a Kurt J. Lesker Torus 2 Magnetron Sputtering Source can be used as the sputtering gun for a DC magnetron sputtering system. The sputter targets 102 can be arranged in any suitable arrangement. For example, four targets 102 can be symmetrically arranged at the bottom of the vacuum chamber 101. For example, the four targets 102 can be arranged to have four-fold rotational symmetry, with the symmetry axis coinciding with the shaft connecting the sample holder 104 and the motor 105. The targets 102 can be inclined towards the sample holder 104. The sample holder 104 can be configured such that a sample placed thereon will face the bottom of the vacuum chamber 101. For example, referring to FIG. 6, a sample 106 can be placed on a sample holder 104. The sample holder 104 can have at least one alignment pin 107. For example, four alignment pins 107 can be symmetrically arranged on sample holder 104, and the first, second, third, and fourth alignment pins 107 can be referred to as a1, a2, a3, and a4, respectively. A clip 108 can hold the sample 106 onto the sample holder 104. In some embodiments, the sample 106 can be placed on the sample holder 104 such that the axis of rotation intersects the sample 106. In other embodiments, the sample 106 can be placed on the sample holder 104 such that the axis of rotation does not intersect the sample 106. For example, the axis of rotation can coincide with the center of the sample holder 104, and the sample 106 can be placed away from the center of the sample holder 104 such that the axis of rotation does not intersect the sample 106.

By way of example and not limitation, during sputtering, the incidence angle of the adatoms from an individual target 102 can have an asymmetric distribution across the surface of the sample 106. This asymmetric distribution can be due to the target 102 having an inclination angle with respect to the surface of the sample 106. Physical rotation of the sample holder 104 can enhance the homogeneity of the sputtered film. The rotation can be controlled by the combination of a motor 105 and a motor controller 111. The magnetic field source 103 can be fixed to the chamber walls and remain stationary. The magnetic field generated by magnetic field source 103 can rotate by programming AC currents running through the coils 103c and 103d. By way of example and not limitation, the data acquisition device 112 can be a National Instruments multiple 10 data acquisition device (NI6212) configured to communicate between the power supplies 113 and 114 and the motor controller 111 and to synchronize the rotating magnetic field with the physical rotation of the sample holder 104.

The motor 105 can be any suitable motor. By way of example and not limitation, the motor 105 can be a stepper motor. For example, the motor 105 can be a Lin Engineering 5718M high torque stepper motor. The motor 105 can be installed on top of the vacuum chamber 101. For example, the motor 105 can be installed on top of the vacuum chamber 101 by a 2¾″ conflat flange (CF) magnetically-coupled rotary feedthrough (Thermionics FRMRE-275-38/MS-EDR) which can be mounted on a linear translator with 2″ of z travel (Thermionics Z-B275C-T275T-1.53-2). The sample holder 104 can be attached to the motor 105 by a shaft.

By way of example and not limitation, the motor controller 111 can be a programmable Thermionics TMC 1-C motor controller configured to control the motor 105 at 800 steps per cycle with a designated angular speed. The motor controller 111 can have a plurality of user input/outputs (I/Os) that can be digital or analog. For example, the motor controller 111 can have 11 I/Os. One of the I/Os can be programmed to change the digital output level between high and low after a desired number of steps, sending out a square wave with a corresponding number of rising edges for each full rotation of the motor 105. For example, one of the I/Os can be programmed to change the digital output level between high and low every 5 steps, sending out a square wave with 80 rising edges for each full rotation of the motor 105. The square wave, which can also be referred to as a pulse train, can be sent to the data acquisition device 112. Thus the clock rate of the data acquisition device 112 can be controlled by the motor controller 111, and the clock rate can be proportional to the rotation speed of the sample holder 104. In this example, for each rotation of the motor 105, 80 clock pulses can occur.

By way of example and not limitation, to implement field sputtering, the magnetic field source 103 can apply a magnetic field. The magnetic field source 103 can be a quadrupole electromagnet, as described above. The electromagnet can have a metallic core. For example, the metallic core can be made of any soft ferromagnetic metal with high permeability and low hysteresis. The metal can be an alloy, such as an alloy based on iron (Fe), cobalt (Co), or nickel (Ni). For example, the core can be a silicon (Si) steel (Fe) core, such as 4% Si Fe from Scientific Alloys. The pairs of coils 103c and 103d can each have a plurality of turns of wire. The wire can be coated in an insulator. For example, each coil in the pairs of coils 103c and 103d can have 250 turns of 14 gauge copper (Cu) wire coated with polyamideimide (NEMA MW 35-C, class 200). The magnetic field source can be suspended from the top of vacuum chamber 101 and fixed as an integrated part of the system 100. The magnetic field source 103 can be centered on the sample holder 104 to form a uniform in-plane magnetic field across the sample holder 104.

By way of example and not limitation, the power supplies 113 and 114 can each be a Kepco bipolar operational power supply (BOP 20-20M). The power supplied 113 and 114 can be connected to the pairs of coils 103e and 103d by a 2¾″ CF electrical feedthrough on the vacuum chamber 101. The power supplies 113 and 114 can be controlled by signals from output channels of the data acquisition device 112.

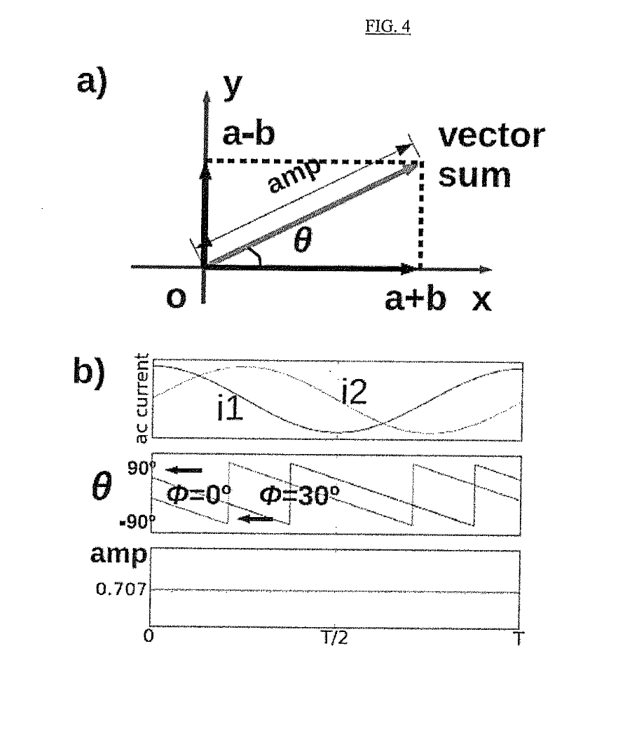

Referring again to FIG. 3, the distribution of magnetic fluxes in the exemplary magnetic field source 103 is shown. Magnetic flux “a” can be generated by the first pair of coils 103c, while flux “b” can be generated by the second pair of coils 103d. The flux flowing through poles p2, p4 can be a+b, and the flux through p1, p3 can be a−b. At the center point O, the magnetic field can be determined by the vector sum of a+b and a−b, as illustrated in FIG. 4(a). If the currents in the pairs of coils 103c and 103d are alternating at a rate of 1 Hz or less, the fluxes can be assumed to follow the instantaneous currents. By applying currents in the form of sin(ωt+φ)×cos(ωt+φ), where ω is the angular speed and φ the initial phase, and separating the currents in the two pairs of coils by a phase difference of π/4, a vector sum of constant norm rotating at the given angular speed can be achieved, as shown in FIG. 4(b). In terms of instrumentation, a desired number of evenly spaced sampling points can be defined on each of the two AC curves i1 and i2 in FIG. 4(b). For example, 80 evenly spaced sampling points can be defined on each of the two AC curves i1 and i2. These two sets of values can be sent to the data acquisition device 112 at the clock rate, which is determined by the motor controller 111. Since there are 80 sampling points for one period of the magnetic field rotation and 80 digital pulses for one rotation of the motor 105, the magnetic field can rotate synchronously with the sample 106. Note that a different number of sampling points can be chosen based on the number of digital pulses representing one full rotation of the motor 105, as described above. To change the angle between the sample reference axis and the magnetic field, the initial phase φ of the AC current curve sin(ωt+φ)×cos(ωt+φ) can be adjusted. This can be programmed in a straightforward manner. For example, the data acquisition device 112 can be programmed directly or can be programmed by an attached computer 120. As shown in FIG. 4(b), a different choice for the initial phase φ can make the magnetic field start rotating at a different angle θ.

Referring to FIG. 5, the linear relationship between the applied voltage control from the data acquisition device 112 and the measured magnitude of the rotating magnetic field is shown. For example, the sample rotation speed can be set to 0.25 RPM and the magnetic field strength can be measured at the sample holder 104 in the x-direction using a Gauss probe. For example, the Gauss probe can be a LakeShore 421 Gauss probe. The input voltage from the data acquisition device 112 can be varied, e.g., from 0 V to 4 V. The measured field strength can show sinusoidal variation with a period of 4 seconds. The amplitudes of the measured sinusoidal curves are shown in FIG. 5. A linear dependence can be observed between the magnetic field amplitude and the amplitude of the AC voltage output of the power supplies.

By way of example and not limitation, a Ta 3 nm/Co_{91.5}Zr_{4.0}Ta_{4.5} 200 nm/SiO₂ 10 nm film can be deposited on 1 cm by 1 cm Si/thermal SiO₂ sample 106 using the system 100 described above with a magnetic field strength of 50 Oe. The 3 nm tantalum (Ta) layer is the seed layer to improve adhesion and homogeneity of the film, and the top silicon dioxide (SiO₂) layer protects the metallic film from oxidation. The ferromagnetic cobalt (Co)-zirconium (Zr)—Ta layer (Co_{91.5}Zr_{4.0}Ta_{4.5} 200 nm) can be DC magnetron sputtered onto the sample 106, with power 400 W, argon (Ar) pressure 1.2 mTorr, and deposition rate 4.3 Å/sec. The alignment of the sample 106 with the sputtering field is demonstrated in FIG. 6. For example, one edge of the sample 106 can be chosen to be the reference axis for the sample 106. When mounted on the sample holder 104, the reference axis can be aligned with the alignment pins 107 labeled a2 and a4 in the x-direction, which can be the default direction of the magnetic field when the initial phase is set to zero. The initial phase φ can be set to any suitable value to change the relative angle between the sputtering field direction and the sample reference axis.

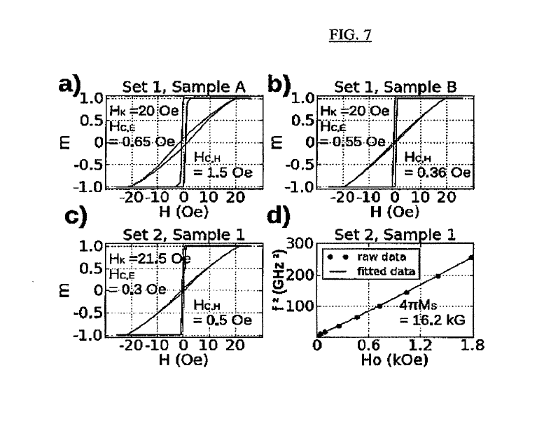

Referring to FIGS. 7(a) and (b), hysteresis (BH) loops of exemplary films are shown. In FIG. 7(a), the film was deposited with the sample holder 104 and the magnetic field remaining stationary during sputtering (no rotation). In FIG. 7(b), the film was deposited with the sample holder 104 and the magnetic field rotating synchronously during sputtering. The BH loops can be measured with a BH loop tracer. Comparing FIGS. 7(a) and (b) can demonstrate that, while both of the exemplary films have an anisotropy field H_{K}=20 Oe and relatively low easy-axis coercivities, the film in FIG. 7(b) can have a more linear response along the hard axis (H_{C,H}=0.36 Oe, compared with 1.5 Oe for FIG. 7(a)).

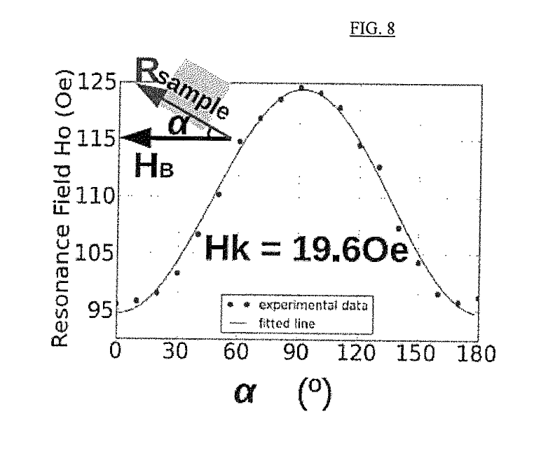

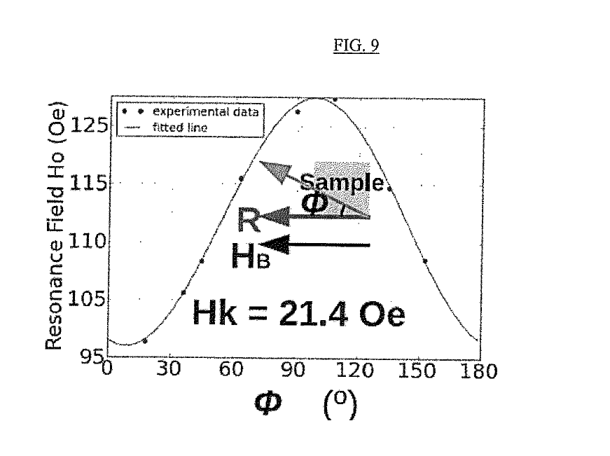

Referring to FIGS. 7(c) and (d), the BH loop and Kittel relation of a ferromagnetic resonance (FMR) field of an exemplary film are shown. By way of example and not limitation, Ta 3 nm/Co_{91.5}Zr_{4.0}Ta_{4.5} 200 nm/SiO₂ 10 nm films can be deposited on 1 cm by 1 cm Si/thermal SiO₂ sample 106 using the system 100 described above with a magnetic field strength of 50 Oe and with phase differences. An exemplary set of nine films, all field-sputtered under rotating magnetic field, with the initial phase of the field set to be φ=0°, 18°, 36°, 45°, 63°, 90°, 108°, 135° and 153°, respectively, can be deposited on nine samples 106. The magnetic properties of the exemplary films can be studied with a BH loop tracer and parallel-condition FMR spectra. As a reference, the BH loop and Kittel relation of the FMR field and frequency for the exemplary film with φ=0° are shown in FIGS. 7 (c) and (d), respectively. The easy axis of the film was measured by the BH loop tracer to be parallel with the sample 106 reference axis, along which the sputtering field was applied. The anisotropy field H_{K} can be 21.5 Oe. The exemplary film can show very low coercivity (H_{C}) along both the easy (H_{C,E}) and the hard (H_{C,H}) axis, with H_{C,E}=0.3 Oe and H_{C,H}=0.5 Oe. Note that the second set of samples can be deposited at a different period of the life time of the Co_{91.5}Zr_{4.0}Ta_{4.5} target 107, and a slight change in the sputtered film composition can occur compared with the first set of samples. This can lead to a change in the uniaxial anisotropy energy of the material. The FMR measurement can give the saturation magnetization of 16.2 kG, using the Kittel relation:

$${( \frac{ω}{2 π} )}^{2} = {γ}^{2} \times ( {H}_{0} + {H}_{K} ) \times ( {H}_{0} + {H}_{K} + 4 π {M}_{S} ) , \qquad ( 1 )$$

where (ω/2φ) is the resonance frequency, γ is the gyromagnetic ratio, H₀ is the resonance bias field, H_{K} is the uniaxial anisotropy field, and 4πM_{S} is the effective saturation magnetization of the film, and assuming g_{eff}=2.2. A rotational FMR measurement at 4 GHz was also performed to investigate the uniaxial anisotropy of the exemplary film with φ=0°. As shown in FIG. 8, the resonance field values (H₀) were recorded as the angle α between the sample 106 reference axis R and the direction of the bias field H_{B} varied at a step of 10 degrees. Note that the angle can have estimated error of ±1.5°. The sinusoidal fit can yield H_{K}=19.6 Oe, which is in reasonable agreement with the value of 21.5 Oe given by the BH loop. FIG. 9 shows the FMR field values at 4 GHz for exemplary films with φ=18°, 36°, 45°, 63°, 90°, 108°, 135° and 153°, when the sample 106 reference axis is parallel with the FMR bias field direction. The data points can sit on a similar curve as in FIG. 8. The sinusoidal fit can give Hₖ=21.4 Oe, in agreement with the value of 21.5 Oe given by the BH loop, and comparable with 19.6 Oe given in FIG. 8. There can be a phase offset of 8.8°, which can be the result of the error in alignment when loading the samples 106 into the sample holder 104.

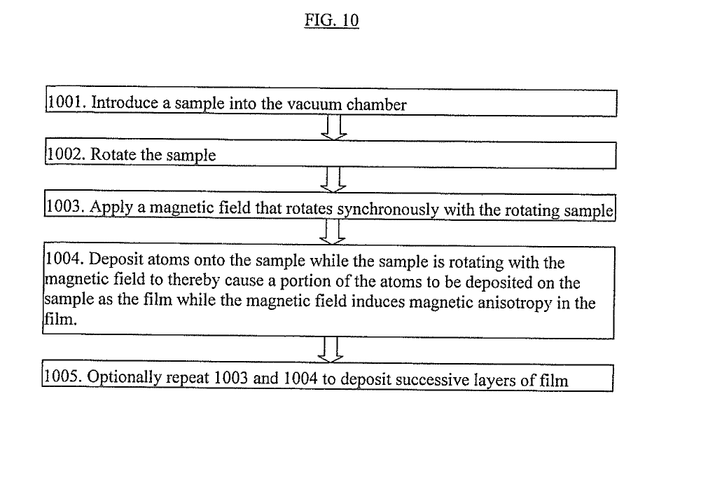

Referring to FIG. 10, an exemplary method for depositing a film in an evacuated vacuum chamber 101 is disclosed. The exemplary method can include introducing the sample 106 into the vacuum chamber 101, as described above (1001). The sample 106 can be rotated, as described above (1002). A magnetic field can be applied that rotates synchronously with the rotating sample 106, as described above (1003). Atoms can be deposited onto the sample 106 while the sample 106 is rotating with the magnetic field to thereby cause a portion of the atoms to be deposited on the sample 106 as the film while the magnetic field induces magnetic anisotropy in the film, as described above (1004). Optionally, the application of the magnetic field (1003) and atom depositing procedure (1004) can be repeated to deposit successive layers of film, as described above (1005).

By way of example and not limitation, the magnetic field can rotate synchronously with the sample 106 with a phase difference, as described above (1003). The rotating of the magnetic field can be achieved by applying sinusoidal AC currents through first and second pairs of coils 103c and 103d wrapped around a quadrupole electromagnet acting as the magnetic field source 103, as described above (1003). In some embodiments, for example when the first and second pairs of coils 103c and 103d are arranged as shown in FIG. 3, the sinusoidal current in the first pair of coils 103c can be π/4 out of phase from the sinusoidal current in the second pair of coils 103d (1003). Depending on the design of the magnetic field source 103 and the positioning of any coils, the sinusoidal currents in the coils could have any suitable phase difference to apply a rotating magnetic field (1003).

By way of example and not limitation, a second magnetic field that rotates synchronously with the sample 106 at a second phase difference can be applied, as described above (1005). For example, the first phase difference and the second phase difference can be π/2 out of phase, thereby depositing successive layers with orthogonal anisotropy, as described above (1005). For example, the first and second phase differences can be any desired value out of phase, including an arbitrary value, thereby depositing successive layers with anisotropies that can form any angle, including an arbitrary angle, according to the phase difference (1005).

By way of example and not limitation, the application of the magnetic field (1003) and atom depositing procedure (1004) can be repeated multiple times to deposit multiple successive layers of film, as described above (1005). For example, for each desired layer, a magnetic field can be applied that rotates synchronously with the sample 106 at a desired phase difference that is different than the phase difference of the preceding layer (1005). Atoms can be deposited while the sample 106 is rotating with the magnetic field to thereby cause a portion of the atoms to be deposited on the sample 106 as a film layer with different anisotropy than the preceding layer, as described above (1005).

By way of example and not limitation, the atoms can be deposited by DC magnetron sputtering, RF sputtering, IBS, IBD, electron beam evaporation, or any other suitable film deposition process, as described above (1004). By way of example and not limitation, atoms can be sputtered from at least one target 102 disposed in the vacuum chamber 101 while the sample 106 is rotating with the magnetic field to thereby cause a portion of the atoms to be deposited on the sample 106 as the film while the magnetic field induces magnetic anisotropy in the film, as described above (1004). By way of example and not limitation, the rotating of the sample 106 and the magnetic field can have a frequency up to 1 revolution per second (1002).

The foregoing merely illustrates the principles of the disclosed subject matter. Various modifications and alterations to the described embodiments will be apparent to those skilled in the art in view of the teachings herein. For example, suitable materials and/or devices different than those discussed above can be used for the various components. It will thus be appreciated that those skilled in the art will be able to devise numerous techniques which, although not explicitly described herein, embody the principles of the disclosed subject matter and are thus within its spirit and scope.

1. A method for depositing a film in an evacuated vacuum chamber, comprising:
introducing a sample into the vacuum chamber;
rotating the sample;
applying a magnetic field that rotates synchronously with the rotating sample; and
depositing atoms onto the sample while the sample is rotating with the magnetic field to thereby cause a portion of the atoms to be deposited on the sample as the film while the magnetic field induces magnetic anisotropy in the film.

2. The method of claim 1, wherein the applying comprises applying a magnetic field that rotates synchronously with the sample at a first phase difference.

3. The method of claim 2, further comprising:
applying a second magnetic field that rotates synchronously with the sample at a second phase difference.

4. The method of claim 3, wherein the phase difference and the second phase difference are π/2 out of phase, thereby depositing successive layers with orthogonal anisotropy.

5. The method of claim 2, further comprising repeating the applying and the depositing to deposit at least a second successive film.

6. The method of claim 2, further comprising:
applying a second magnetic field that rotates synchronously with the sample at a second phase difference that is different than the first phase difference; and
depositing atoms onto the sample while the sample is rotating with the second magnetic field to thereby cause a portion of the atoms to be deposited on the sample as a second film while the second magnetic field induces magnetic anisotropy in the second film.

7. The method of claim 1, wherein the applying comprises applying sinusoidal currents through first and second pairs of coils wrapped around a quadrupole electromagnet core, wherein the sinusoidal current in the first pair of coils is π/4 out of phase from the sinusoidal current in the second pair of coils.

8. The method of claim 1, wherein the rotating has a frequency of at most 1 revolution per second.

9. The method of claim 1, wherein the introducing comprises centering the sample in the vacuum chamber.

10. The method of claim 1, wherein the depositing comprises one of direct current (DC) magnetron sputtering, radio frequency (RF) sputtering, or ion beam sputtering (IBS), ion beam deposition (IBD), or electron beam evaporation.

11. The method of claim 1, wherein the depositing comprises sputtering atoms from at least one target disposed in the vacuum chamber.

12. The method of claim 11, wherein the sputtering comprises sputtering atoms from at least one target that is inclined towards the sample.

13. A system for vacuum film deposition, comprising:
a vacuum chamber;
a physical vapor deposition device disposed in the vacuum chamber;
a sample holder disposed in the vacuum chamber;
a motor configured to rotate the sample holder; and
a magnetic field source adapted to rotate a magnetic field synchronously with the sample holder.

14. The system of claim 13, wherein the magnetic field source comprises a quadrupole electromagnet.

15. The system of claim 14, wherein the quadrupole electromagnet comprises:
a metallic core comprising a circular core ring and first, second, third, and fourth poles equidistantly spaced around the interior of the circular core ring, each of the poles protruding towards the center of the circular core ring;
a first pair of coils comprising a first coil wrapped around the metallic core between the first and fourth poles and a second coil wrapped around the metallic core between the second and third poles; and
a second pair of coils comprising a third coil wrapped around the metallic core between the first and second poles and a fourth coil wrapped around the metallic core between the third and fourth poles.

16. The system of claim 15, further comprising:
a motor controller configured to control the motor;
at least one power supply configured to generate alternating current (AC) currents through the first and second pairs of coils; and
a data acquisition device connected to the motor controller and the at least one power supply to synchronize the rotating of the magnetic field and the rotating of the sample holder.

17. The system of claim 15 wherein the quadrupole electromagnet is positioned to be centered with the sample holder, thereby allowing a uniform in-plane magnetic field across the sample holder.

18. The system of claim 15, wherein the quadrupole electromagnet is configured to generate a magnetic field that rotates synchronously with the sample at a phase difference.

19. The system of claim 13, wherein the physical vapor deposition device comprises one of a DC magnetron sputtering system, a RF sputtering system, an IBS system, and IBD system, or an electron beam evaporation system.

20. The system of claim 13, wherein the physical vapor deposition device comprises a sputtering device adapted to sputter atoms from at least one sputter target disposed in the vacuum chamber.
